(19) United States
(12) Patent Application Publication
(10) Pub. No.: US 2025/0300006 A1
(43) Pub. Date: Sep. 25, 2025

(54) SPLIT CONDUCTIVE VIA FABRICATION

(71) Applicant: IMEC VZW, Leuven (BE)

(72) Inventors: Seongho Park, Heverlee (BE); Zsolt Tokei, Leuven (BE)

(21) Appl. No.: 19/082,564

(22) Filed: Mar. 18, 2025

(30) Foreign Application Priority Data
Mar. 22, 2024 (EP) 24165436.7

(51) Int. Cl. H01L 21/768

(52) U.S. Cl. CPC H01L 21/76816; H01L 21/76834; H01L 21/76837; H01L 21/76897

(57) ABSTRACT

The present disclosure relates to a method for forming an integrated circuit or an intermediate thereof. The method includes providing a second electrically conductive layer over a first electrically conductive line and in electrical contact with it, followed by etching the second layer to form a part of an electrically conductive via with a bottom surface, an exposed top surface smaller or equal to the bottom, and sidewalls. A third electrically conductive layer is then formed on the via, connecting the first line with the third layer. Subsequent etching through these layers forms a set of electrically conductive lines, splits the via, and interrupts the first line. This method provides the formation of electrical connections within an integrated circuit, which is useful for the performance and miniaturization of electronic devices.

### CROSS-REFERENCE TO RELATED APPLICATION(S)

The present application is a non-provisional patent application claiming priority to European Patent Application No. 24165436.7, filed Mar. 22, 2024, the contents of which are hereby incorporated by reference.

### FIELD OF THE DISCLOSURE

The present disclosure pertains to the field of semiconductor device fabrication, including methods for forming integrated circuits with improved conductive via structures.

### BACKGROUND

The field of semiconductor manufacturing has seen progress over the past several decades, driven by the industry's ability to scale down the size of transistors and the interconnects that link them together. This miniaturization has been useful in increasing the performance and functionality of electronic devices while reducing power consumption and cost. The process of scaling is governed by a set of design rules, referred to as ground rules (GRs), provide the minimum dimensions and tolerances for the various features that make up a semiconductor device.

Semiconductor fabrication includes the formation of conductive vias and metal layers that create the electrical connections between different parts of the integrated circuit. As devices have become more complex and the demand for higher performance has increased, the industry has faced challenges in maintaining the pace of scaling. These challenges are evident in the context of the Copper Dual-Damascene (Cu DD) process, which has been a useful approach for forming these connections. FIG. 1 portrays a sequence of four diagrams that illustrate the stages of the dual damascene process, a method for forming metal interconnections within an integrated circuit.

The first diagram of FIG. 1, shows (e.g., at the bottom) a first electrically conductive layer (Mx). This electrically conductive layer (Mx) is covered by a conductive barrier layer (3). On top of the conductive barrier layer (3), there is a dielectric material (10), in which via holes have been patterned using a mask (14). These via holes are designed to eventually house the electrically conductive material that will form a conductive vias (2) of the circuit. As shown in FIG. 3A, via holes have a bottom surface (4a) and sloped sidewalls (6a) wherein the angle (a) between the bottom surface (4a) and the sidewalls (6a) is greater than 90° around the periphery of the bottom surface (4a).

The second diagram of FIG. 1, shows the subsequent stage where an electrically conductive material, such as copper, has been deposited into the openings, filling them, thereby forming the conductive vias (2). The conductive material also covers the (e.g., entire) assembly, indicating an overfill forming an interconnect layer (Mx+1) above and in contact with the conductive via (2). A masking material (14) is provided on top of the interconnect layer (Mx+1).

In the third diagram of FIG. 1, the masking material (14) has been patterned and used as a mask (14) to etch through the interconnect layer (Mx+1) and the conductive via (2), thereby splitting it in two.

The fourth and final diagram of FIG. 1 illustrates the result after a further etching step, where the barrier layer and the first electrically conductive line (Mx) have been split as well.

In the Cu DD process, conductive vias often extend beyond the metal layers (Mx and Mx+1), which may lead to inefficiencies in the use of space within the semiconductor layout and/or short-circuits. The conductive via center-to-center (C2C) spacing is limited by lithographic capabilities, which restricts how closely these vias may be placed to one another. Similarly, the trench-to-trench (T2T) spacing is constrained by both lithography and etching processes. These limitations become more pronounced as the industry pushes towards smaller pitches, testing the limits of current manufacturing technologies.

Alignment offsets and etching selectivity are concerns that may impact the yield and performance of semiconductor devices. As pitches shrink, the alignment accuracy between different layers and features becomes increasingly critical. Misalignment may lead to defects and functional failures, making the manufacturing process more complex and costly.

Despite the advancements in lithography and etching techniques, there is a recognition within the industry that the (e.g., traditional) Cu DD process may not be sufficient to meet the demands of future scaling. The challenges associated with conductive via imperfect overlap, C2C spacing, and T2T spacing highlight the need for new approaches that may overcome these hurdles.

The concept of self-aligning conductive vias to metal layers has been used as a potential way to achieve more efficient use of space within the semiconductor layout. However, the practical implementation of this concept faces significant challenges, particularly as the industry continues to scale down to smaller nodes.

In light of these challenges, further advancements are sought in the field of semiconductor manufacturing that address these challenges.

### SUMMARY

Example embodiments of the present disclosure provide (e.g., tight) conductive via-to-conductive via and trench-to-trench spacing in semiconductor fabrication and a method for forming an integrated circuit or an intermediate in the formation thereof.

In the first aspect, the present disclosure relates to a method for forming an integrated circuit or an intermediate in the formation thereof. The method includes the steps of a. providing a second electrically conductive layer over a first electrically conductive line and in electrical contact therewith, then b. etching the second electrically conductive layer to form at least a lower part of an electrically conductive via having a bottom surface having a first area, an exposed top surface having a second area, smaller or equal to the first area, and sidewalls, such as sloped sidewalls, connecting the bottom surface to the top surface, wherein the angle between the bottom surface and the sidewalls is at most 90° around the periphery of the bottom surface, c. forming a third electrically conductive layer on the at least a lower part of the electrically conductive via, thereby making electrical contact with the exposed top surface and electrically connecting the first electrically conductive line with the third electrically conductive layer, and d. etching through the third electrically conductive layer, the electrically conductive via, and the first electrically conductive line, to form i. a set of electrically conductive lines from the third electrically conductive layer, the electrically conductive lines being separated by gaps, ii. splitting the electrically conductive via into a first split electrically conductive via and a second split electrically conductive via, and iii. splitting the first electrically conductive line.

In example embodiments, step b. of the method may further include i. providing a hard mask over a region of the second electrically conductive layer, ii. etching the second electrically conductive layer by using the hard mask as an etching guide, thereby forming the lower part of the electrically conductive via. Step c. includes i. depositing a dielectric material to fill a gap around the lower part of the electrically conductive via to expose a top surface of the hard mask, ii. removing the hard mask, thereby leaving a hole exposing the top surface of the lower part of the electrically conductive via, and iii. forming an upper part of the electrically conductive via in addition to the third electrically conductive layer, wherein the upper part of the electrically conductive via is aligned and makes electrical contact with the top surface of the lower part of the electrically conductive via. This embodiment provides an example of a practical implementation of the first aspect, providing a (e.g., precise) method for forming the electrically conductive via with a controlled shape and size.

In example embodiments, the hard mask may have a thickness of from 1 nm to 5 nm. A hard mask with a thickness as small as possible allows step c to be performed without having to fill too large a gap left by the removal of the hard mask. This avoids defect creation during step c.

In example embodiments where it is used, the dielectric material may be a silicon oxide. This embodiment uses silicon oxide (e.g., a commonly used dielectric material) to provide good electrical insulation and compatibility with semiconductor processes.

In example embodiments, step c.i may include depositing a dielectric material to fill a gap around the lower part of the electrically conductive via and to cover the hard mask, followed by planarizing the dialectical material by chemical mechanical planarization to expose the top surface of the hard mask. This embodiment provides a smooth and level surface for subsequent processing steps.

In example embodiments, the width of the bottom surface of the via may be from 3 times to 3.5 times larger than the width of the lines of the set of electrically conductive lines. The use of a large pillar conductive via obtained by a subtractive method may lead to a larger interface between metal layers and the conductive vias, which may result in a larger process window and less variation of conductive via resistance. For example, it allows for the formation of two vias, after splitting, with a (e.g., sufficiently) large bottom surface, which may improve the electrical connection to the first electrically conductive line Mx and reduce resistance.

In example embodiments, the method may include d1. of providing a hard mask including a set of parallel lines separated by gaps, the lines being in physical contact with a top surface of the third electrically conductive layer, two of the lines overlapping with the electrically conductive via so that the width of a vertical projection of the gap between both lines on the top surface of the electrically conductive via is provided in that top surface, and then d2. of etching (i) the third electrically conductive layer, (ii) the electrically conductive via, and (iii) the first electrically conductive line, by using the hard mask lines as an etching guide. This embodiment provides a method for (e.g., precisely) providing (e.g., defining) the location and size of the gap between the split vias.

In example embodiments, the hard mask may include Si₃N₄. This embodiment uses silicon nitride (e.g., a material with good etch selectivity with respect to metals and with good mechanical properties), as the silicon nitride is suitable for use as a hard mask.

In example embodiments, the hard mask may further include a TiN layer between the Si₃N₄ and the third electrically conductive layer. The TiN layer may act as a diffusion barrier and improve the adhesion between the hard mask and the conductive layer.

In example embodiments, the method may include providing a semiconductor structure including two transistor structures, the first electrically conductive line extending above at least part of each transistor structure, a second electrically conductive via electrically connecting the first electrically conductive line with a first of the transistor structures, and a third electrically conductive via electrically connecting the first electrically conductive line with a second of the transistor structures. This is an example embodiment of the first aspect, as it integrates the formation of the electrically conductive vias with the underlying transistor structures, facilitating the creation of (e.g., complex) integrated circuits.

In example embodiments, the method may further include covering with a masking material a portion of the first electrically conductive line which may not be exposed by a gap while leaving the gap uncovered. This embodiment protects (e.g., certain) areas of the conductive line during etching, providing for (e.g., more precise) patterning.

In example embodiments, the masking material may be a spin-on carbon material. Spin-on carbon provides a uniform coating and may be easily applied to the substrate.

In example embodiments, the second electrically conductive layer, the first electrically conductive line, and the third electrically conductive layer may be provided in the form of (e.g., made of) Cu, W, Mo, or Ru (e.g., preferably Ru). These materials provide suitable (e.g., good) electrical conductivity and are compatible with semiconductor processing.

In example embodiments, a conductive barrier layer may be provided between the second electrically conductive layer and the first electrically conductive line. The barrier layer may improve the reliability of the electrical connection.

In example embodiments, the conductive barrier layer may be a TiN layer. Titanium nitride is a conductive barrier material that provides suitable (e.g., good) adhesion and barrier properties.

In example embodiments, the present disclosure relates to a method for forming an integrated circuit for use in a device having at least one of a computer processor, a memory chip, and a sensor. This example embodiment highlights the broad applicability of the method to various types of electronic devices.

Embodiments of the present disclosure mitigates the challenges associated with conductive via overlap in conventional Copper Dual-Damascene processes. Example embodiments of the present disclosure further overcome the limitations of conductive via center-to-center spacing, dictated by lithographic capabilities. Embodiments of the present disclosure also reduce trench-to-trench spacing, supporting the trend of continuous scaling in semiconductor fabrication. Embodiments of the present disclosure address alignment offsets, which are (e.g., critical) considerations in semiconductor manufacturing. Embodiments of the present disclosure using a split conductive via provides tighter conductive via-to-conductive via and trench-to-trench spacing. The present disclosure that use the semi-damascene process allows for configurations not feasible in traditional Copper Dual-Damascene processes. Embodiments of the present disclosure that use a large pillar conductive via obtained by a subtractive method may lead to a larger interface between metal layers and the conductive vias, which may result in a larger process window and less variation of conductive via resistance. The present disclosure has the angle between the bottom surface and the sidewalls of the conductive via being at most 90 degrees, enhancing the electrical contact between layers. Embodiments of the present disclosure provide that the process may lead to more efficient use of space within the semiconductor layout, potentially improving the performance of semiconductor devices at smaller scales.

Particular aspects of the disclosure are set out in the accompanying independent and dependent claims. Features from the dependent claims may be combined with features of the independent claims and with features of other dependent claims as appropriate and not merely as set out in the claims.

The above and other characteristics and features of the present disclosure may become apparent from the following detailed description, taken in conjunction with the accompanying drawings, which illustrate, by way of example, the principles of the disclosure. This description is given for the sake of example, without limiting the scope of the disclosure.

### BRIEF DESCRIPTION OF THE FIGURES

The above, as well as additional, features will be better understood through the following illustrative and non-limiting detailed description of example embodiments, with reference to the appended drawings.

FIG. 1 is a cross-sectional view of a series of intermediates in the fabrication of a semiconductor structure, illustrating the dual damascene process of the prior art.

FIGS. 2A, 2B, 2C, and 2D are cross-sectional views of intermediates in the fabrication of a semiconductor structure, illustrating the process according to an embodiment of the present disclosure.

FIG. 3A is a cross-sectional view of an angle (α) obtained in the prior art.

FIG. 3B is a cross-sectional view of an angle (α) of the present disclosure.

FIG. 4 is a flowchart of the method for forming an integrated circuit or an intermediate in the formation thereof according to embodiments of the present disclosure. In the different figures, the same reference signs refer to the same or analogous elements.

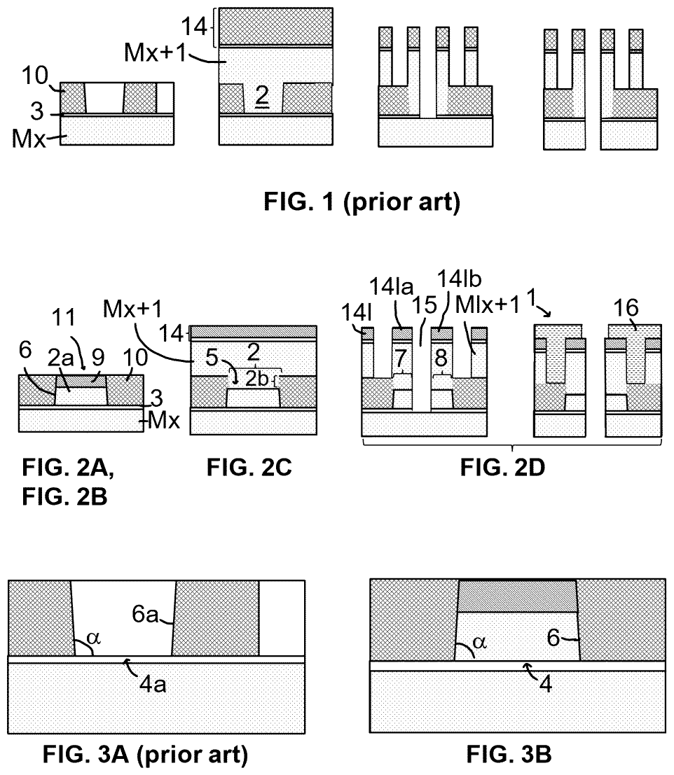

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The present disclosure will be described with respect to particular embodiments and with reference to certain drawings, but the disclosure is not limited thereto. The drawings described are schematic and are non-limiting. In the drawings, the size of some of the elements may be exaggerated and not drawn on scale for illustrative purposes. The dimensions and the relative dimensions may not correspond to actual reductions to practice of the disclosure.

The terms first, second, third, and the like in the description and in the claims, distinguish between similar elements and may not necessarily describe a sequence, either temporally, spatially, in ranking, or in any other manner. These terms are interchangeable under appropriate circumstances and the embodiments of the disclosure described herein are capable of operation in other sequences than described or illustrated herein.

Moreover, the terms top, over, and the like in the description and the claims are used for descriptive purposes and not necessarily for describing relative positions. The terms top, over, and the like so used are interchangeable under appropriate circumstances and the embodiments of the disclosure described herein are capable of operation in other orientations than described or illustrated herein.

The term “comprising”, also used in the claims, should not be interpreted as being restricted to the means listed thereafter. This term does not exclude other elements or steps. It is thus to be interpreted as specifying the presence of the stated features, integers, steps, or components as referred to, but does not preclude the presence or addition of one or more other features, integers, steps or components, or groups thereof. Thus, the scope of the expression “a device comprising means A and B” should not be interpreted as being limited to devices including only components A and B. It means that with respect to the present disclosure, the relevant components of the device are A and B. The term “comprising” therefore covers the situation where the stated features are present, and the situation where these features and one or more other features are present. The word “comprising” according to the disclosure therefore also includes at least one embodiment where no further components are present. When the word “comprising” is used to describe an embodiment in this application, an alternative version of the same embodiment, wherein the term “comprising” is replaced by “consisting of”, is also encompassed within the scope of the present disclosure.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, in one or more embodiments.

Similarly, it should be appreciated that in the description of exemplary embodiments of the disclosure, various features of the disclosure are sometimes grouped together in a single embodiment, figure, or description thereof for streamlining the disclosure and aiding in the understanding of one or more of the various inventive aspects. This method of disclosure, however, is not to be interpreted as reflecting an intention that the claimed disclosure requires more features than are (e.g., expressly) recited in each claim. Rather, as the following claims reflect, inventive aspects may lie in less than all features of a single foregoing disclosed embodiment. Thus, the claims following the detailed description are hereby (e.g., expressly) incorporated into this detailed description, with each claim standing on its own as a separate embodiment of this disclosure.

Furthermore, while some embodiments described herein include some, but not other features included in other embodiments, combinations of features of different embodiments are meant to be within the scope of the disclosure and may form different embodiments. For example, in the following claims, the claimed embodiments may be used in any combination.

Furthermore, some of the embodiments are described herein as a method or combination of elements of a method that may be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for carrying out the disclosure.

In the description provided herein, numerous specific details are set forth. However, embodiments of the disclosure may be practiced without these specific details. In other instances, methods, structures, and techniques may not be shown in detail to not obscure an understanding of this description.

The disclosure will now be described by a detailed description of several embodiments of the disclosure. Other embodiments of the disclosure may be provided without departing from the technical teaching of the disclosure, the disclosure is limited only by the terms of the appended claims.

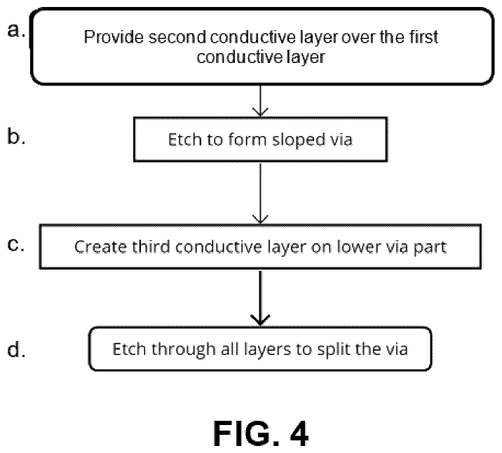

Referring to FIGS. 2A, 2B, 2C, and 2D and 4, FIGS. 2A-2D are cross-sectional views of a semiconductor structure illustrating the process according to an embodiment of the present disclosure, showing the etched lower part (2a) of an electrically conductive via (2) with sloped sidewalls (6) and a third electrically conductive layer (Mx+1) formed on it. FIG. 4 is a flowchart of the method for forming an integrated circuit or an intermediate (1) in the formation thereof according to embodiments of the present disclosure, outlining the steps of the method, including (a) the provision of the second conductive layer over the first conductive line or layer, (b) etching the second conductive layer to form a via with an angle (α) of at most 90°, or a sloped via with an angle (α) below 90°, (c) creating a third conductive layer on the lower via part, and (d) the formation of the split electrically conductive vias by etching.

The present disclosure relates to a method for forming an integrated circuit or an intermediate (1) in the formation thereof. The method includes providing a second electrically conductive layer (not depicted) over a first electrically conductive line (Mx) and in electrical contact therewith. The first electrically conductive line (Mx) may be part of a first electrically conductive layer. The first electrically conductive layer may comprise a plurality of parallel first electrically conductive lines (Mx). The second electrically conductive layer is etched to form at least a lower part (2a) of an electrically conductive via (2). This via has a bottom surface (4) with a first area, an exposed top surface (5) with a second area smaller or equal to the first area, and sidewalls (6), or sloped sidewalls, connecting the bottom surface (4) to the top surface (5). The angle (α) between the bottom surface (4) and the sidewalls (6) is at most 90°, or below 90°, (e.g., all) around the periphery of the bottom surface (4), as illustrated in FIGS. 3A and 3B, which compares the angle (α) obtained in the prior art (FIG. 3A) with the present disclosure (FIG. 3B). FIG. 3B shows the via according to the present disclosure, where the angle (α) between the bottom surface (4) and the sidewalls (6) is less than 90°, resulting in a (e.g., larger) interface between the first electrically conductive line (Mx) (e.g., or the conductive barrier layer (3) thereon) and the electrically conductive vias (2).

A third electrically conductive layer (Mx+1) is formed on the lower part (2a) of the electrically conductive via (2), making electrical contact with the exposed top surface (5) and electrically connecting the first electrically conductive line (Mx) with the third electrically conductive layer (Mx+1). The third electrically conductive layer (Mx+1), the electrically conductive via (2), and the first electrically conductive line (Mx) are then etched to form a set of electrically conductive lines (Mlx+1) separated by gaps (15), splitting the electrically conductive via into a first and a second split electrically conductive via (7, 8), and splitting the first electrically conductive line (Mx). This “split conductive via” provides tighter conductive via-to-conductive via and trench-to-trench spacing, supporting (e.g., continuous) scaling in semiconductor fabrication.

Herein, the term “integrated circuit or an intermediate” may refer to a (e.g., complete) electronic circuit with various components such as transistors, resistors, capacitors, and the interconnects between them, or to a partially completed structure of such a circuit that is in the process of being fabricated. Example embodiments include but are not limited to microprocessors, memory chips, digital signal processors, and application-specific integrated circuits (ASICs).

Herein, the term “electrically conductive layer or line” may refer to (e.g., respectively) a layer or a line of material having the ability to conduct electric current. This term encompasses layers made of metals, metal alloys, conductive oxides, or any other materials known to have conductive properties. Example embodiments include layers provided in the form of (e.g., made of) copper (Cu), tungsten (W), molybdenum (Mo), ruthenium (Ru), aluminum (Al), and their alloys. These electrically conductive layers or lines may be deposited by a suitable method, such as ALD or CVD.

In example embodiments, the first electrically conductive line (Mx) may be embedded in a dielectric material, such as SiO₂. In example embodiments, the first electrically conductive line (Mx) may be provided as part of a set of parallel first electrically conductive lines (Mx), (e.g., all) arranged within a first metallization level and (e.g., each) extending along a same first direction.

Herein, the term “electrically conductive via” may refer to a structure (e.g., oriented vertically) that provides an electrical connection between different layers of an integrated circuit. The via is composed of conductive material and is characterized by having a bottom surface, an exposed top surface, and sloped sidewalls.

In the fabrication process, the formation of an electrically conductive via involves step b of etching the second electrically conductive layer to form at least a lower part of an electrically conductive via. This etching facilitates the creation of a via with a straight or inclined profile, wherein the sidewalls form an angle of 90 degrees or less than 90 degrees with respect to the base. This (e.g., precise) angulation may be achieved through direct metal etch, which halts upon reaching the etch stop layer that resides atop the underlying Mx lines. The direct metal etch techniques may be adapted to various electrically conductive materials such as Copper (Cu), Ruthenium (Ru), Molybdenum (Mo), and Tungsten (W), among others. Direct metal etch techniques may involve exposing the electrically conductive material to a chemically reactive plasma. Examples of (e.g., direct) metal etch techniques are reactive ion etching and atomic layer etching. Depending on the material composition of the conductive layer, suitable etchant gases and conditions may be selected. For example, when the layer is composed of Ru, Chlorine (Cl₂) or a combination of Oxygen (O₂) with Cl₂ may be employed as the etchant (e.g., in an inductively coupled plasma etching chamber). This (e.g., non-traditional) approach of forming the via, characterized by its sidewalls angled at 90° or lower, offers an improvement over the (e.g., conventional) damascene process, which may involve dielectric etching followed by metal filling. The unique angle of the via facilitates a more efficient electrical connection and also provides a larger process window, enhancing the reliability and performance of the semiconductor device.

The term “at least a lower part of the electrically conductive via” encompasses both incomplete vias and complete vias. When (e.g., only) a lower part of the electrically conductive via is formed, the height of this lower part is (e.g., preferably) at least 90% of the height of the (e.g., entire) via obtained after step c.

The angle (α) between the bottom surface (4) and the sidewalls (6) is at most 90°, or from 80° to 88°. This angle may be determined by TEM imaging.

In example embodiments, step b. of the method may include i. providing a hard mask (9) over a region of the second electrically conductive layer. The hard mask provided in step b.i. is patterned to provide (e.g., comprise) a through hole. The shape of the through hole may determine the shape of the via hole, and hence the shape of the electrically conductive via. This shape may, for instance, be circular or square. The hard mask (9) is used as an etching guide to form the lower part (2a) of the electrically conductive via (2) during etching step ii.

Herein, the term “hard mask” may refer to a layer of material that is resistant to etching processes and is used to provide (e.g., define) patterns during the etching of underlying layers. The hard mask serves as a protective barrier in selected areas while allowing the removal of unprotected material. Examples embodiments may include hard masks made of silicon nitride (Si₃N₄), silicon carbide (SiC), titanium nitride (TiN), and other materials provided for their etch resistance.

The hard mask (9) may have a thickness of from 1 nm to 5 nm. It may be provided in the form of (e.g., comprise) Si₃N₄ or may further be provided in the form of (e.g., comprise) a TiN layer between the Si₃N₄ and the third electrically conductive layer (Mx+1).

Step c. may include forming either a third electrically conductive layer (Mx+1) having a flat bottom surface when the at least a lower part of the electrically conductive via is the (e.g., whole final) electrically conductive via, or a third electrically conductive layer (Mx+1) penetrating a via hole in a dielectric material (10), the via hole exposing the lower part of the electrically conductive via, thereby forming the upper part of the electrically conductive via, when the at least a lower part of the electrically conductive via is (e.g., only) a lower part of the electrically conductive via. Forming the third electrically conductive layer (Mx+1) may, for example, be performed by PVD, CVD, or ALD.

Herein, the term “dielectric material” may refer to a non-conductive material used to electrically isolate different conductive elements within an integrated circuit. This material is used to fill gaps and spaces between conductive features. Example embodiments include silicon oxide (SiO₂), low-k dielectrics, high-k dielectrics, and other insulating materials commonly used in semiconductor fabrication.

During step c.i., a dielectric material (10), which may, for example, be a silicon oxide, is deposited to fill a gap around the lower part (2a) of the electrically conductive via (2), to expose a top surface (11) of the hard mask (9). The hard mask (9) is then removed in step c.ii., leaving a hole exposing the top surface (5) of the lower part (2a) of the electrically conductive via (2). An upper part (2b) of the electrically conductive via (2) is then formed in step c.iii. in addition to the third electrically conductive layer (Mx+1), wherein the upper part of the electrically conductive via (2) is aligned and makes electrical contact with the top surface (5) of the lower part (2a) of the electrically conductive via (2).

Embodiments of the process flow of the disclosure involves etch, gap fill, Chemical Mechanical Planarization (CMP), oxide recess, and optional hard mask (HM) (e.g., Silicon Nitride (Si₃N₄)) removal.

An example way to provide that the dielectric material fills the gap around the lower part of the electrically conductive via while also exposing a top surface of the hard mask is to proceed with chemical mechanical planarization (CMP).

Herein, the term “chemical mechanical planarization” (CMP) may refer to a process that combines application of an excess of a material (e.g., a dielectric material), followed by a mechanical polishing to flatten and smooth the surface of the applied material, thereby removing excess material and providing a (e.g., uniform) surface for subsequent processing steps. Examples embodiments include CMP processes for planarizing dielectric layers, metal layers, and barrier layers. This process is used to planarize the topography of the material and is useful when the applied material is meant to be coplanar with features of the substrate on which it has been applied.

The dielectric material (10) may be planarized by chemical mechanical planarization to expose the top surface (11) of the hard mask (9).

The width of the bottom surface (4) of the via (2) may be from 3 times to 3.5 times larger than the width of the lines of the set of electrically conductive lines (Mlx+1), providing the conductive via critical dimension (CD) as three to three and a half times the CD of the Mx+1 layer.

Step c.iii. may be performed as described earlier, e.g., by forming either a third electrically conductive layer (Mx+1) having a flat bottom surface when the at least a lower part of the electrically conductive via is the whole final electrically conductive via, or a third electrically conductive layer (Mx+1) penetrating a via hole in a dielectric, the via hole exposing the lower part of the electrically conductive via, thereby forming the upper part of the electrically conductive via, when the at least a lower part of the electrically conductive via is (e.g., only) a lower part of the electrically conductive via.

In example embodiments, the set of electrically conductive lines (Mlx+1) formed in step d.i. may have a width of 5 nm to 20 nm.

The pitch of the set of parallel lines (141) may be the same as the pitch of the set of electrically conductive lines (Mlx+1).

In example embodiments, the width of the split created in step d. ii. may be 0.4 times to 0.6 times, e.g., 0.5 times, the pitch of the set of electrically conductive lines (Mlx+1).

In example embodiments, the distance separating the first split electrically conductive via (7), and the second split electrically conductive via (8) may be from 0.4 times to 0.6 times, e.g., 0.5 times, the pitch of the set of electrically conductive lines (Mlx+1).

In example embodiments, the width of each of the first split electrically conductive via (7), and a second split electrically conductive via (8) may be from 5 nm to 13 nm.

In example embodiments, the distance separating the first split electrically conductive via (7) and a second split electrically conductive via (8) may be from 5 to 13 nm.

In some embodiments, step d. of the method may include d1. providing a hard mask (14) comprising a set of parallel lines (141) separated by gaps. These lines (141) are in (e.g., physical) contact with a top surface of the third electrically conductive layer (Mx+1), and two of the lines (141a, 141b) overlap with the electrically conductive via (2). The width of a vertical projection of the gap between both lines (141a, 141b) on the top surface of the electrically conductive via (2) is provided (e.g., comprised) in that top surface. The third electrically conductive layer (Mx+1) and the electrically conductive via (2) are then etched using the hard mask lines (141) as an etching guide. This approach proposes a (e.g., self-aligning) conductive via to metal layers for efficient space use within the semiconductor layout.

In example embodiments, the set of parallel lines (141) may be equidistant.

The method may also include providing a semiconductor structure comprising two transistor structures, with the first electrically conductive line (Mx) extending above at least part of each transistor structure. A second electrically conductive via electrically connects the first electrically conductive line (Mx) with a first of the transistor structures, and a third electrically conductive via electrically connects the first electrically conductive line (Mx) with a second of the transistor structures. A portion of the first electrically conductive line (Mx) which is not exposed by a gap (15) may be covered with a masking material, such as a spin-on carbon material, while leaving the gap (15) uncovered.

Herein, the term “semiconductor structure” may refer to a structure that includes semiconductor devices and the associated interconnects and layers that form part of an integrated circuit. Examples embodiments include structures containing transistor devices such as metal-oxide-semiconductor field-effect transistors (MOSFETs), bipolar junction transistors (BJTs), FinFETs, GAA FETs, and CFETs, among others.

Herein, the term “masking material” may refer to a material applied to protect certain areas of a semiconductor wafer during processing steps such as etching or implantation. This material prevents modification of the underlying areas while allowing processing of exposed regions. Examples embodiments include photoresist materials, spin-on carbon materials, and hard masks.

In example embodiments, the second electrically conductive layer, the first electrically conductive line (Mx), and the third electrically conductive layer (Mx+1) may be provided in the form of (e.g., made of) Cu, W, Mo, or Ru (e.g., preferably Ru).

In example embodiments, a conductive barrier layer (3), which may be a TiN layer, may be provided between the second electrically conductive layer and the first electrically conductive line (Mx). Ruthenium (Ru) deposition after etching to the next metal layer (Mx+1) is included in the process (12).

Herein, the term “conductive barrier layer” may refer to a thin layer of conductive material that is used as an etch stop layer and which may, in some embodiments, enhance adhesion between different materials in an integrated circuit. Examples embodiments include barrier layers made of titanium nitride (TiN), tantalum nitride (TaN), and other materials provided for their conductive and barrier properties.

In example embodiments, the method of the present disclosure may be for forming an integrated circuit for use in a device selected from at least one of a computer processor, a memory chip, and a sensor.

Although example embodiments, specific constructions, and configurations, as well as materials, have been discussed herein for devices according to the present disclosure, various changes or modifications in form and detail may be made without departing from the scope of this disclosure. For example, any formulas given above are representative of procedures that may be used. Functionality may be added or deleted from the block diagrams and operations may be interchanged among functional blocks. Steps may be added or deleted to methods described within the scope of the present disclosure.

While some embodiments have been illustrated and described in detail in the appended drawings and the foregoing description, such illustration and description are to be considered illustrative and not restrictive. Other variations to the disclosed embodiments may be understood and effected in practicing the claims, from a study of the drawings, the disclosure, and the appended claims. The fact that measures or features are recited in mutually different dependent claims does not indicate that a combination of these measures or features may not be used. Any reference signs in the claims should not be construed as limiting the scope.

What is claimed is:

1. A method for forming an integrated circuit or an intermediate, the method comprising:
providing a second electrically conductive layer over a first electrically conductive line, wherein the second electrically conductive layer and the first electrically conductive line are in electrical contact;
etching the second electrically conductive layer to form a lower part of an electrically conductive via having a bottom surface having a first area, an exposed top surface having a second area, smaller or equal to the first area, and sidewalls connecting the bottom surface to the top surface, wherein an angle between the bottom surface and the sidewalls is equal to or less than about 90° around a periphery of the bottom surface;
forming a third electrically conductive layer on the lower part of the electrically conductive via, to form electrical contact with the exposed top surface and electrically connecting the first electrically conductive line with the third electrically conductive layer; and
etching through the third electrically conductive layer, the electrically conductive via, and the first electrically conductive line, to
form a set of electrically conductive lines from the third electrically conductive layer, the set of electrically conductive lines being separated by gaps,
split the electrically conductive via into a first split electrically conductive via and a second split electrically conductive via, and
split the first electrically conductive line.

2. The method according to claim 1, wherein etching the second electrically conductive layer includes providing a hard mask over a region of the second electrically conductive layer.

3. The method according to claim 2, wherein etching the second electrically conductive layer includes using the hard mask as an etching guide to form the lower part of the electrically conductive via.

4. The method according to claim 2, wherein forming the third electrically conductive layer includes depositing a dielectric material to fill a gap around the lower part of the electrically conductive via to expose a top surface of the hard mask.

5. The method according to claim 2, wherein forming the third electrically conductive layer includes removing the hard mask, thereby leaving a hole exposing the top surface of the lower part of the electrically conductive via.

6. The method according to claim 1, wherein forming a third electrically conductive layer includes forming an upper part of the electrically conductive via in addition to the third electrically conductive layer, wherein the upper part of the electrically conductive via is aligned and makes electrical contact with the top surface of the lower part of the electrically conductive via.

7. The method according to claim 2, wherein the hard mask has a thickness of 1 nm to 5 nm.

8. The method according to claim 2, wherein the dielectric material is a silicon oxide.

9. The method according to claim 2, wherein forming the set of electrically conductive lines includes depositing a dielectric material to fill a gap around the lower part of the electrically conductive via and to cover the hard mask, followed by planarizing the dielectric material by chemical mechanical planarization to expose the top surface of the hard mask.

10. The method according to claim 1, wherein a width of the bottom surface of the electrically conductive via is from 3 times to 3.5 times larger than a width of lines of the set of electrically conductive lines.

11. The method according to claim 1, wherein etching through the third electrically conductive layer, the electrically conductive via, and the first electrically conductive line includes providing a hard mask including a set of parallel lines separated by gaps, wherein the lines being in contact with a top surface of the third electrically conductive layer, and wherein two of the lines overlap with the electrically conductive via for the width of a vertical projection of the gap between the two lines on the top surface of the electrically conductive via.

12. The method according to claim 11, wherein etching through the third electrically conductive layer, the electrically conductive via includes etching by using the hard mask lines as an etching guide.

13. The method according to claim 11, wherein the hard mask is provided in the form of Si₃N₄.

14. The method according to claim 13, wherein the hard mask further includes a TiN layer between the Si₃N₄ and the third electrically conductive layer.

15. The method according to claim 1, wherein providing a second electrically conductive layer over a first electrically conductive line and in electrical contact therewith includes two transistor structures, the first electrically conductive line extending above at least part of each transistor structure, a second electrically conductive via electrically connecting the first electrically conductive line with a first of the transistor structures, and a third electrically conductive via electrically connecting the first electrically conductive line with a second of the transistor structures.

16. The method according to claim 1, further comprising covering with a masking material a portion of the first electrically conductive line which is not exposed by a gap while leaving the gap uncovered, wherein the covering with the masking material is between forming a set of electrically conductive lines and splitting the first electrically conductive line.

17. The method according to claim 11, wherein the masking material is a spin-on carbon material.

18. The method according to claim 1, wherein the second electrically conductive layer, the first electrically conductive line, and the third electrically conductive layer are provided in the form of Ru.

19. The method according to claim 1, wherein a conductive barrier layer is provided between the second electrically conductive layer and the first electrically conductive line.

20. The method according to claim 19, wherein the conductive barrier layer is a TiN layer.
